(19) United States
(12) Patent Application Publication
(10) Pub. No.: US 2008/0253422 A1
(43) Pub. Date: Oct. 16, 2008

(54) Surface emitting semiconductor laser

(76) Inventor: Yutaka Onishi, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/076,240

(22) Filed: Mar. 14, 2008

(30) Foreign Application Priority Data
Mar. 20, 2007 (JP) P2007-073068

(51) Int. Cl. H01S 5/00

(52) U.S. Cl. 372/50.11

(57) ABSTRACT

A surface emitting semiconductor laser comprises first and second distributed Bragg reflectors, an active layer and a junction region. The first distributed Bragg reflector includes first III-V compound semiconductor layers and second III-V compound semiconductor layers, and the first and second III-V compound semiconductor layers are alternately arranged. The second distributed Bragg reflector includes a first portion and a second portion. The first portion including third III-V compound semiconductor layers and fourth III-V compound semiconductor layers, and the third and fourth III-V compound semiconductor layers are alternately arranged. The second portion includes first insulating layers and second insulating layers, and the first and second insulating layers are alternately arranged. The active layer is provided between the first distributed Bragg reflector and the second distributed Bragg reflector. The active layer is made of III-V compound semiconductor. The first portion of the second distributed Bragg reflector is provided between the active layer and the second portion. The junction region includes a tunnel junction, and the junction region is provided between the active layer and the second distributed Bragg reflector.

### BACKGROUND OF THE INVENTION

1. Field of the Invention

The present invention relates to a surface emitting semiconductor laser.

2. Related Background Art

Non-patent document 1 (N. Nishiyama et al., Electronics Letters, vol. 39, no. 5, pp. 437-439, 2003.) discloses a buried tunnel junction surface emitting semiconductor laser. This semiconductor laser includes AlGaInAs/InP distributed Bragg reflector mounted on an InP substrate, an active layer, and an n-type InP layer for burying a tunnel junction, and an a-Si/Al₂O₃ insulating distributed Bragg reflector (insulating DBR) is provided on the n-type InP layer.

### SUMMARY OF THE INVENTION

In the surface emitting semiconductor laser disclosed in Non-patent document 1, since the insulating DBR has a poor thermal conductivity, the temperature of the surface emitting laser is increased by heat generated during operations. The temperature increase causes the output saturation in the surface emitting laser.

Since the insulating DBR does not pass an electric current therethrough, a top electrode is located on a contact layer formed on the InP layer to avoid the insulating DBR. Current from the electrode flows through the n-type InP layer in a transverse direction, and passes through the tunnel junction to the active layer. The current flows over great distance, and the total resistance cannot be reduced. The optical cavity should be shortened in order to reduce the threshold current of the surface emitting laser, and therefore the n-type InP cannot be made thicker without limit. In addition, heat load is applied to the tunnel junction in growing films after forming it, and diffuses dopant atoms in the tunnel junction. This dopant diffusion deteriorates the electrical characteristics of the tunnel junction. From the view point of dopant diffusion, it is not preferable that the n-type InP layer be made thicker. In each case, in order to reduce heat generated by the laser during operations, it is not preferable to increase the thickness of the n-type InP layer for reducing the resistance of the path from the electrode to the tunnel junction.

It is an object to provide a surface emitting semiconductor laser which can improve heat dissipation due to the insulating DBR.

A surface emitting semiconductor laser according to one aspect of the present invention comprises a first distributed Bragg reflector, a second distributed Bragg reflector, an active layer and a junction region. The first distributed Bragg reflector includes first III-V compound semiconductor layers and second III-V compound semiconductor layers, and the first and second III-V compound semiconductor layers are alternately arranged. The second distributed Bragg reflector includes a first portion and a second portion. The first portion includes third III-V compound semiconductor layers and fourth III-V compound semiconductor layers, and the third and fourth III-V compound semiconductor layers are alternately arranged. The second portion includes first insulating layers and second insulating layers, and the first and second insulating layers are alternately arranged. The active layer is provided between the first distributed Bragg reflector and the second distributed Bragg reflector. The active layer is made of III-V compound semiconductor. The first portion of the second distributed Bragg reflector is provided between the active layer and the second portion. The junction region includes a tunnel junction, and the junction region is provided between the active layer and the second distributed Bragg reflector.

In the surface emitting semiconductor laser according to the present invention, the surface emitting semiconductor laser further comprises a first spacer layer. The first spacer layer is provided between the active layer and the second distributed Bragg reflector. The first spacer region includes a primary surface. The primary surface has a first area and a second area, and the second area surrounds the first area. The junction region has a tunnel mesa. The tunnel mesa is located on the first area. The tunnel mesa is made of a first conductive type III-V compound semiconductor layer and a second conductive type III-V compound semiconductor layer. The first spacer region is made of a second conductive type III-V compound semiconductor.

In the surface emitting semiconductor laser according to the present invention, the surface emitting semiconductor laser further comprises a second spacer layer. The second spacer layer is provided between the first spacer layer and the second distributed Bragg reflector. The second spacer layer is made of a first conductive type III-V compound semiconductor. The second spacer layer covers a side and a top of the tunnel mesa. The second spacer layer and the second area of the first spacer layer are arranged to form a junction.

In the surface emitting semiconductor laser according to the present invention, the first portion of the second distributed Bragg reflector has a primary surface. The primary surface includes a first area and a second area, and the second area surrounds the first area. The second portion of the second distributed Bragg reflector is provided on the first area of the second distributed Bragg reflector.

In the surface emitting semiconductor laser according to the present invention, the surface emitting semiconductor laser comprises a first electrode. The first electrode is provided on the second area of the first portion of the second distributed Bragg reflector.

In the surface emitting semiconductor laser according to the present invention, the second spacer layer has a primary surface. The primary surface includes a first area and a second area, and the second area surrounds the first area. The second distributed Bragg reflector is provided on the first area of the second spacer layer. The surface emitting semiconductor laser further comprising a first electrode, and the first electrode is provided on the second area of the second spacer layer.

In the surface emitting semiconductor laser according to the present invention, the third and fourth III-V compound semiconductor layers of the second distributed Bragg reflector are undoped.

In the surface emitting semiconductor laser according to the present invention, the third III-V compound semiconductor layers are doped with dopant of a first conductive type and the fourth III-V compound semiconductor layers are doped with dopant of the first conductive type.

In the surface emitting semiconductor laser according to the present invention, the first III-V compound semiconductor layers are doped with dopant of the first conductive type and the second III-V compound semiconductor layers are doped with dopant of the first conductive type.

In the surface emitting semiconductor laser according to the present invention, the top area of the first portion of the second distributed Bragg reflector is different from that of the second portion of the second distributed Bragg reflector.

In the surface emitting semiconductor laser according to the present invention, the top area of the second portion of the second distributed Bragg reflector is smaller than the top areas of the first distributed Bragg reflector and the first portion of the second distributed Bragg reflector.

The surface emitting semiconductor laser according to claim 1, further comprising a substrate, the first distributed Bragg reflector, second distributed Bragg reflector, active layer and junction region are provided on a first surface of the substrate.

The surface emitting semiconductor laser according to claim 1, further comprising a second electrode, the second electrode is provided on a second surface of the substrate, the first surface is opposite to the second surface.

### BRIEF DESCRIPTION OF THE DRAWINGS

The above object and other objects, features, and advantages of the present invention will be understood easily from the following detailed description of the preferred embodiments of the present invention with reference to the accompanying drawings.

FIG. 1 is a schematic view showing a surface emitting semiconductor laser according to the present invention.

FIG. 2 is a graph showing the differential resistance of the tunnel junctions in five kinds of surface emitting semiconductor laser devices.

FIG. 3 is a graph showing the differential resistance of the tunnel junctions in eight kinds of surface emitting semiconductor laser devices.

FIG. 4 is a schematic view showing a device structure (A) for the surface emitting semiconductor laser shown in FIG. 1.

FIG. 5 is a schematic view showing a device structure (B) which does not include any insulating DBR working as the second DBR, and a device structure (C) which does not include any semiconductor DBR working as the second DBR.

FIG. 6 is a schematic view showing a modified surface emitting semiconductor laser according to the present invention.

### DETAILED DESCRIPTION OF THE PREFERRED EMBODIMENTS

The teachings of the present invention will readily be understood in view of the following detailed description with reference to the accompanying drawings illustrated by way of example. Referring to the accompanying drawings, embodiments of a surface emitting semiconductor laser of the present invention will be explained. When possible, parts identical to each other will be referred to with symbols identical to each other.

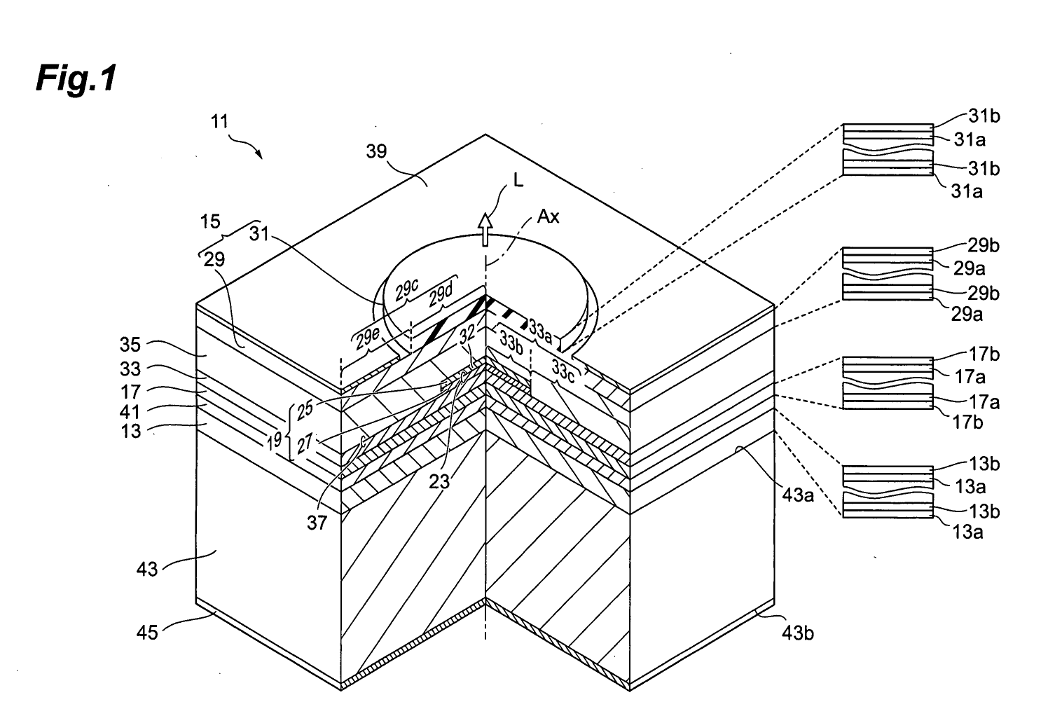

FIG. 1 is a schematic view showing a surface emitting semiconductor laser according to the embodiment of the present invention. The surface emitting semiconductor laser 11 comprises a first distributed Bragg reflector 13, a second distributed Bragg reflector 15, an active layer 17, and a junction region 19. The first distributed Bragg reflector 13 includes a plurality of first III-V compound semiconductor layers 13a and a plurality of second III-V compound semiconductor layers 13b, and the first and second III-V compound semiconductor layers 13a, 13b are alternately arranged so as to form the distributed Bragg reflector. The active layer 17 is provided between the first distributed Bragg reflector 13 and the second distributed Bragg reflector 15, and is made of III-V compound semiconductor. The junction region 19 includes a tunnel junction 23, and is provided between the active layer 17 and the second distributed Bragg reflector 15. The junction region 19 includes a semiconductor layer 25 of a first conductive type (for example, n-type) and a semiconductor layer 27 of a second conductive type (for example, p-type), and the first conductive type semiconductor layer 25 and second conductive type semiconductor layer 27 are arranged to form the tunnel junction 23. The second distributed Bragg reflector 15 includes a first portion 29 and a second portion 31. The first portion 29 includes a plurality of third III-V compound semiconductor layers 29a and a plurality of fourth III-V compound semiconductor layers 29b. The third and fourth III-V compound semiconductor layers 29a and 29b are alternately arranged so as to form a semiconductor laminate for a semiconductor distributed Bragg reflector. The second portion 31 includes a plurality of first insulating layers 31a and a plurality of second insulating layers 31b, and the first and second insulating layers 31a and 31b are alternately arranged so as to form an insulating laminate for an insulating distributed Bragg reflector. In the second distributed Bragg reflector 15, the first and second portions 29 and 31 are arranged so as to form the second distributed Bragg reflector 15. The first portion 29 is located between the second portion 31 and the active layer 17.

The thermal conduction of the semiconductor laminate of the second distributed Bragg reflector is greater than that of the insulating laminate of the distributed Bragg reflector. Since a part of the second distributed Bragg reflector, i.e., the semiconductor distributed Bragg reflector, is made of the semiconductor layers 29a and 29b, the thermal conductivity of the semiconductor distributed Bragg reflector becomes excellent as compared with that of the insulating distributed Bragg reflector.

The active layer 17 has a quantum well structure, a bulk structure or the like. When the active layer has a quantum well structure, the quantum well structure includes well layers 17a and barrier layers 17b, and each well layer 17a is located between the barrier layers 17b.

The first and second distributed Bragg reflectors 13, 17 form an optical cavity. The active layer 17 is provided between the first and second distributed Bragg reflectors 13 and 17, and light from the active layer is reflected by the first and second distributed Bragg reflectors 13 and 17 to emit a laser beam “L.” The wavelength of the laser beam “L” is referred to as “λ.” It is preferable that the length of the optical cavity be equal to a value obtained by dividing the wavelength “λ” of the laser beam “L” by the equivalent refractive index of the optical cavity. The location of the tunnel junction 23 is adjusted to a node of the electric field standing wave at which the amplitude of the relevant electric field standing wave of the laser beam “L” becomes zero. This adjustment minimizes the absorption of the laser beam “L” by the junction region 19 that is doped heavily. The location of the active layer 17 is adjusted to an antinodes of the electric field standing wave at which the amplitude of the relevant electric field standing wave of the laser beam “L” becomes maximum. This adjustment maximizes the lasing gain of the surface emitting semiconductor laser.

The surface emitting semiconductor laser 11 further includes a first spacer layer 33. The first spacer layer 33 is made of III-V compound semiconductor of the second conductive type, and is provided between the active layer 17 and the second distributed Bragg reflector 15. The first spacer layer 33 has a primary surface 33a, and the primary surface 33a includes a first area 33b and a second area 33c. The second area 33c surrounds the first area 33b. The junction region 19 has a tunnel mesa 32 located on the first area 33b of the first spacer layer 33.

In the surface emitting semiconductor laser 11, the tunnel mesa 32 performs conversion of the type of charge carriers, that is, electrons to holes, alternatively holes to electrons. The converted carriers flow to the first spacer layer 33 made of a first conductive type III-V compound semiconductor.

The surface emitting semiconductor laser 11 further includes a second spacer layer 35. The second spacer layer 35 is provided between the first spacer layer 33 and the second distributed Bragg reflector 15. The second spacer layer 35 is made of a first conductive type III-V compound semiconductor. The top and the side of the tunnel mesa 32 are covered with the second spacer layer 35. The second area 33c of the second spacer layer 33 and the second spacer layer 35 form a pn junction 37.

In the surface emitting semiconductor laser 11, current is confined by the tunnel mesa 32 and the junction 37 formed by the second area 33c of the second spacer layer 33 and the second spacer layer 35.

In the surface emitting semiconductor laser 11, the first portion 29 of the second distributed Bragg reflector 15 has a primary surface 29c, and the primary surface 29c includes a first area 29d and a second area 29e. The second area 29e surrounds the first area 29d. The second portion 31 of the second distributed Bragg reflector 15 is located on the first area 29c.

Since the second portion 31 of the second distributed Bragg reflector 15 is located on the first area 29, not on the whole of the primary surface 29c, the first portion 29 works well for dissipating heat generated in the surface emitting semiconductor laser 11. The first portion 29 covers the whole of the second spacer layer 35, and thus carriers to the tunnel mesa 32 flow through the second spacer layer 35 and the first portion 29 of the second distributed Bragg reflector 15. The first distributed Bragg reflector 13, the active layer, and the first and second portions 29, 31 of the second distributed Bragg reflector 15 are arranged on a predetermined axis, and the bottom area of the second portion 31 is larger than that of the junction region 19. The junction region 19 performs the confinement of current. The transverse mode of lasing can be adjusted by the sizes of the tunnel mesa 32 and second portion 31.

The surface emitting semiconductor laser 11 further comprises a first electrode 39 provided on the second area 29e of the second portion 29.

According to the surface emitting semiconductor laser 11, current from the first electrode 39 to the junction region 19 flows through the first portion 29 of the second distributed Bragg reflector 15 as well as the second spacer layer 35. The surface emitting semiconductor laser 11 can reduce the resistance of the current path from the first electrode 39 to the junction region 19 without increasing the thickness of the second spacer layer 35.

The surface emitting semiconductor laser 11 includes a third spacer layer 41 provided between the active layer 17 and the first distributed Bragg reflector 13. The third spacer layer 41 is made of III-V compound semiconductor of the first conductive type. The third spacer layer 41 supplies one of two kinds of charge carriers (for example, electron) to the active layer 17 and provides a potential barrier to the other (for example, hole) in the active layer. In order to supply charge carriers in the third spacer layer 41, it is preferable that the first and second III-V compound semiconductor layers 13a and 13b have the first conductive type. Further, since the first spacer layer 33 is made of III-V compound semiconductor of the second conductive type, the first spacer layer 33 supplies the other of two kinds of charge carriers (for example, hole) to the active layer 17 and provides a potential barrier to the one of two kinds of carriers (for example, electron) in the active layer.

The surface emitting semiconductor laser 11 includes a substrate 43. The substrate 43 can be made of III-V compound semiconductor, such as GaAs and InP. On the primary side 43a of the substrate 43, a semiconductor laminate including the first distributed Bragg reflector 13 and other semiconductor layers is mounted. A second electrode 45 is provided on the backside 43b of the substrate 43. In one example of the surface emitting semiconductor laser 11, the first electrode 39 can be used as an anode, whereas the second electrode 45 can be used as a cathode.

Since the surface emitting semiconductor laser 11 includes the junction region 19 having the tunnel mesa 23, the third and fourth III-V compound semiconductor layers 29a and 29b are doped with dopant of the first conductive type, not the second conductive type.

### Example 1

Subsequently, one example of the present invention will be described. In order to investigate the thermal tolerance of characteristics of the tunnel junction, the inventor conducted the following experiments. Crystal growth in the experiments can be performed by use of metal-organic-vapor-phase epitaxy method. A carbon-doped GaAs layer, a junction region including a tunnel junction, and a silicon-doped GaAs layer are sequentially grown on a p-type substrate. The tunnel junction is constituted by a carbon-doped In_{0.1}Ga_{0.9}As layer and a silicon-doped In_{0.1}Ga_{0.9}As layer, and the carbon-doped In_{0.1}Ga_{0.9}As layer and silicon-doped In_{0.1}Ga_{0.9}As layer work as heavily-doped p-type and n-type layers, respectively. The concentrations of hole and electron in the tunnel junction are 5×10⁻¹⁹ cm⁻³ and 5×10⁻¹⁸ cm⁻³, respectively. An SiO₂ film is formed by sputtering on the junction region. After a contact window of five-micrometer diameter is formed by etching, an n-side electrode is formed thereon. A p-side electrode is formed on the whole of the backside of the GaAs substrate.

In order to investigate changes in characteristics of the tunnel junction caused by semiconductor growth after the tunnel junction has been formed, the first experiment is conducted. Si-doped GaAs films are grown on GaAs substrates for two hours at growth temperatures of 500° C., 550° C., 600° C., 650° C. and 700° C. to form five kinds of epitaxial wafers.

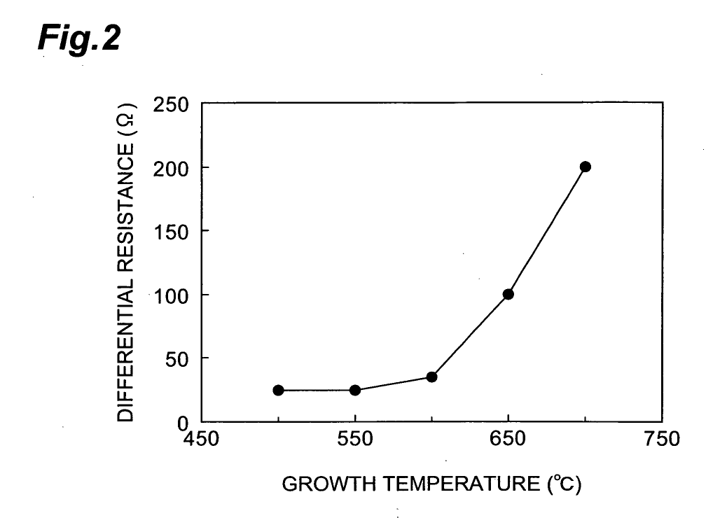

FIG. 2 shows differential resistance characteristics obtained by measuring the five kinds of epitaxial wafers. The differential resistance defines a resistance value around zero applied voltage. FIG. 2 reveals that the differential resistance values are increased with increase of the growth temperatures of the Si-doped GaAs films. When the growth temperatures are higher than 600° C., the increasing rate of differential resistance becomes remarkably high because greater heat load applied to the tunnel junction causes greater diffusion of dopant atoms therein.

Other experiments are conducted by use of epitaxial wafers of the same structure as the above. Si-doped GaAs films are grown on GaAs substrates for 0.5 hours, one hour, 2 hours and 3 hours at the growth temperatures of 650° C. and 700° C. to form eight kinds of epitaxial wafers.

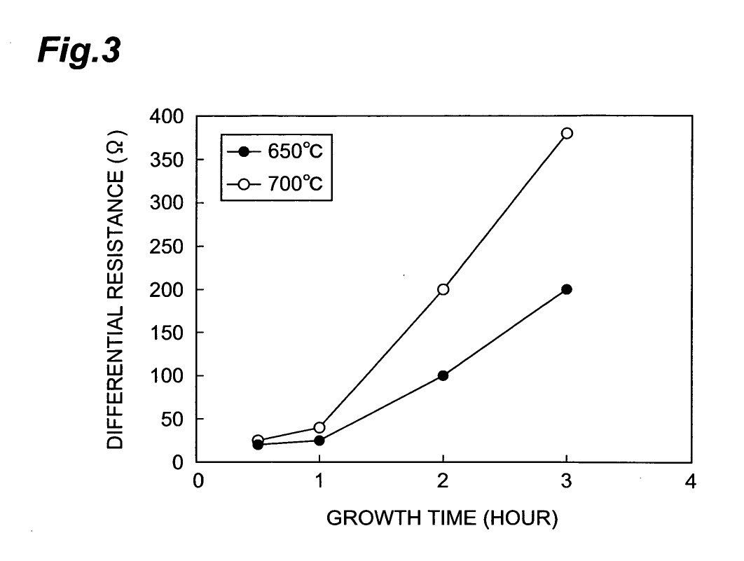

FIG. 3 shows differential resistance characteristics obtained by measuring the five kinds of epitaxial wafers. FIG. 3 reveals that the differential resistance values are increased with increase of the above growth time. When the growth time is longer than one hour, the increasing rate of differential resistance becomes remarkably high because heat load applied to the tunnel junction causes greater diffusion of dopant atoms therein.

### Example 2

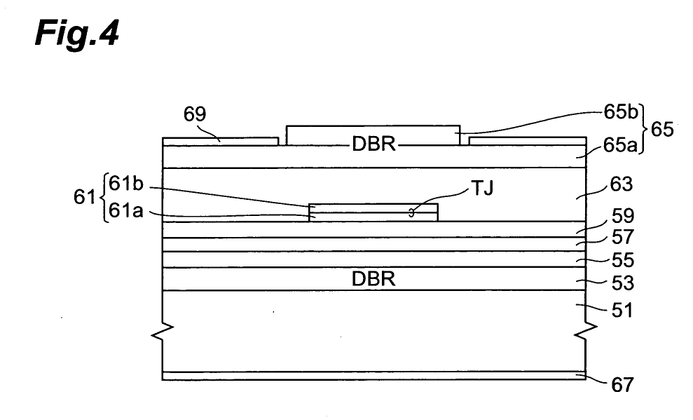

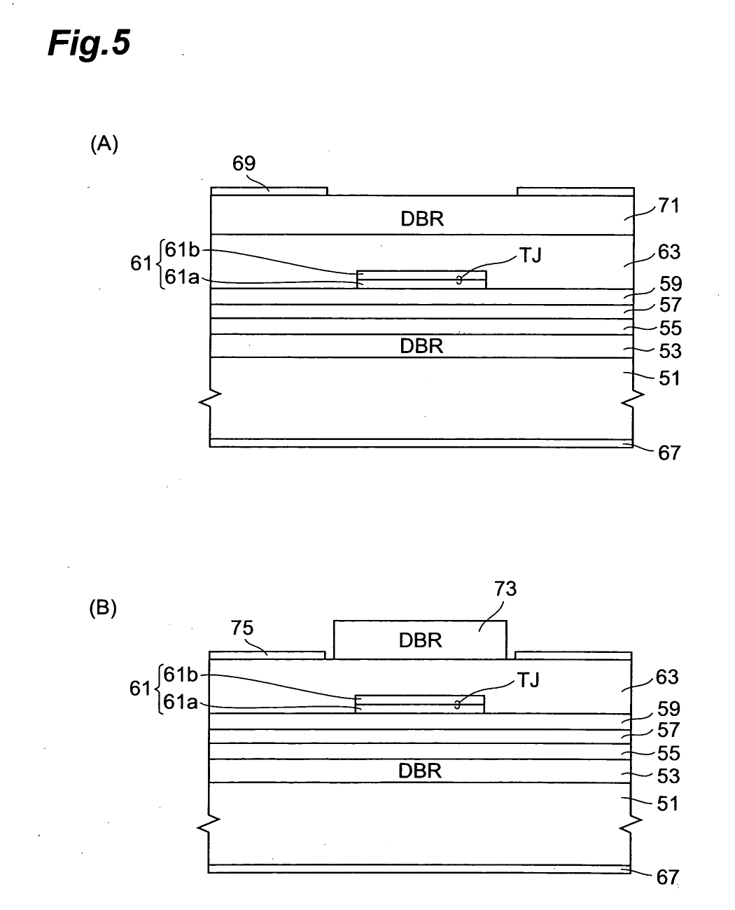

Next, a surface emitting semiconductor laser is fabricated as follows. A distributed Bragg reflector (referred as to “first DBR” in this example) 53 is made on an n-type GaAs substrate 51. The first DBR 53 includes 32 pairs of GaAs/Al_{0.9}Ga_{0.1}As layers. These semiconductor layers are doped with n-type dopant, such as Si. If required, a Si-doped GaAs layer is deposited on the first DBR 53, and this Si-doped GaAs layer is used as a spacer layer 55. Next, an active layer 57 of a quantum well structure is fabricated on the spacer layer 55. The active layer 57 includes three In_{0.2}Ga_{0.8}As well layers and GaAs barrier layers. On the active layer 57, a p-type GaAs layer 59 is grown, and the p-type GaAs layer 59 is doped with carbon. On the p-type GaAs layer 59, semiconductor films for the tunnel junction are grown. A tunnel junction region includes a heavily doped pn junction TJ made of carbon-doped InGaAs (61a)/silicon-doped InGaAs (61b). The growth temperature of the tunnel junction region is, for example, 600° C. An epitaxial wafer is fabricated by the above steps, and this epitaxial wafer is taken out from the reactor. A resist mask having a diameter of 5 micrometers is formed by use of photolithography. The tunnel junction region is removed by wet etching to form a tunnel mesa 61 of a diameter of 5 micrometers. The processed epitaxial wafer is cleaned, and then is placed in the reactor. A silicon-doped GaAs spacer layer 63 is grown at a temperature of 500° C. Next, a distributed Bragg reflector (referred to as “semiconductor DBR” in this example) 65a is fabricated. The semiconductor DBR 65a includes eight pairs of GaAs/Al_{0.9}Ga_{0.1}As, for example, and these semiconductor layers are doped with n-type dopant, such as Si. An electrode 67 is formed on the whole of the backside of the n-type GaAs substrate 51, whereas an electrode 69 having an opening of a diameter of 10 micrometers is formed on the semiconductor DBR 65a. The circular opening is used for the emitting of light. Thereafter, an insulating DBR 65b is formed. The insulating DBR 65b includes two kinds of insulating layers differing in refractive index, and these two kinds of insulating layers are alternately arranged. The insulating DBR 65b includes two pairs of amorphous-Si/Al₂O₃. The part of the insulating layers on the electrode 69 is removed by lift-off. The semiconductor DBR 65a and insulating DBR 65b form a second DBR 65. FIG. 4 shows the structure (A) of the above device, and this device structure (A) is fabricated to demonstrate a surface emitting semiconductor laser as shown in FIG. 1. Another surface emitting semiconductor laser is fabricated. In the fabrication of this surface emitting semiconductor laser, a semiconductor DBR having 14 pairs of semiconductor layers is formed in place of the insulating DBR, and the other surface emitting semiconductor laser includes a semiconductor DBR 71 having 22 pairs of semiconductor layers in total, and has the device structure (B) that does not use any insulating DBR as the second semiconductor DBR. Part (A) of FIG. 5 shows the device structure (B).

Still another surface emitting semiconductor laser is fabricated. In the fabrication of this surface emitting semiconductor laser, a semiconductor DBR having two pairs of insulating layers is formed in place of the semiconductor DBR, and the above surface emitting semiconductor laser includes a second DBR 73 having four pairs of amorphous-Si/Al₂O₃ layers in total, and has the device structure (C) that does not use any semiconductor DBR as the second semiconductor DBR. Part (B) of FIG. 5 shows the device structure (C). In the device structure (A, B, C), the tunnel junctions of these device structures are positioned to the antinodes of the respective standing waves in order to minimize the absorption of light, and the active layers are positioned to the nodes of the respective standing waves in order to maximize the lasing gains. The optical cavity length of the device structure (A, B, C) is equal to a value obtained by dividing the wavelength “λ” of the laser beam “L” by the equivalent refractive index of optical cavities. The differential resistance and maximum optical output of the device structures (A, B, C) are measured at room temperature, and the measured values of differential resistance/maximum optical output in the device structures (A, B, C) are 50Ω/2 mW, 200Ω/2 mW and 250Ω/1.5 mW, respectively. The differential resistance of the device structure (B) is higher than that of the device structure (A) because the dopant atoms in the tunnel junction are diffused in the growth of the second DBR (upper DBR). The maximum optical output of the device structure (B) is lower than that of the device structure (A) because the semiconductor DBR in the device structure (B) absorbs light propagating in the cavity and the optical output of the device structure (B) is saturated by rise in heat due to the large resistance. The differential resistance of the device structure (C) is larger than that of the device structure (A) and (B) because the transverse component of current is increased by the thin Si-doped GaAs spacer layer formed on the tunnel junction. The maximum optical output of the device structure (C) is lower than the maximum optical outputs of the device structures (A) and (B) because the optical output of the device structure (C) is saturated by rise in heat due to the poor heat dissipation of the insulating DBR.

The above experiments show that the maximum optical outputs in the above surface emitting semiconductor lasers are restricted by rise in heat caused by their poor heat dissipation, and what is needed to avoid temperature increase is a structure providing both low device resistance and excellent heat dissipation, e.g., low heat resistance.

In the device structure (A) as shown in FIG. 4, since the growth time for the semiconductor DBR is not long, the diffusion of dopant atoms in the tunnel junction is made small. Further, since current from an electrode to the tunnel junction flows through the semiconductor DBR in addition to the Si-doped GaAs spacer layer that covers the tunnel junction, the semiconductor region that the above current flows through is made thick and the transverse component of the current is made small. Furthermore, the semiconductor DBR works well for heat dissipation to avoid the saturation in optical output accordingly. This results in the surface emitting semiconductor laser with a short optical cavity length that provides both low electrical resistance and high optical output.

### Example 3

A surface emitting semiconductor laser can be formed on InP substrates in place of GaAs substrates. A first DBR including 40 pairs of AlGaInAs/InP, an active layer of a quantum well structure including three AlGaInAs well layers, a carbon-doped AlInAs spacer layer, a heavily-doped pn junction “TJ” including carbon-doped p-type AlGaInAs/silicon-doped n-type AlGaInAs are formed on an n-type InP substrate using a reactor to form an epitaxial wafer. The growth temperature of the tunnel junction is, for example, 500° C. The epitaxial wafer is taken out from the reactor. A photomask of a diameter of five micrometers is formed on the epitaxial wafer by use of photolithography. The tunnel junction region is removed by wet etching to form a tunnel mesa of a diameter of five micrometers. After the above processing of the epitaxial wafer, the processed epitaxial wafer is cleaned, and is placed on the reactor again. In the next step, a silicon-doped InP spacer is grown thereon at temperature of 500° C., and a semiconductor DBR including eight pairs of AlGaInAs/InP are grown at temperature of 650° C., and these semiconductor layers are doped with n-type dopant, such as silicon. An electrode is formed on the whole of the backside of the n-type InP substrate. Another electrode having a circular opening of a diameter of 10 micrometers is formed on the semiconductor DBR, and this opening is used for the emitting of light. In the next step, an insulating DBR is formed thereon. The insulating DBR has the alternation of two kinds of insulating films differing in refractive index. The insulating DBR includes two pairs of amorphous-Si/Al₂O₃, for example. The part of the insulating alternation on the electrode is removed by lift-off. The semiconductor DBR and insulating DBR form the second DBR. FIG. 4 shows a device structure (A), and the device structure (A) is fabricated to demonstrate the structure of the surface emitting semiconductor laser as shown in FIG. 1. Device structures (B, C) are also fabricated as described in Example 2. The device structure (B) is made of InP-based semiconductor, and includes a semiconductor DBR working as the second DBR. The device structure (C) is made of InP-based semiconductor, and includes an insulating DBR working as the second DBR. In these device structures (A, B, C), the tunnel junctions are positioned to the nodes of standing waves in order to minimize absorption of light, and the active layers are positioned to the antinodes of standing waves in order to maximize their gains. The optical cavity length of the device structures (A, B, C) is equal to a value obtained by dividing the wavelength “λ” of the laser beam “L” by the equivalent refractive index of the optical cavity.

Like the GaAs-based surface emitting semiconductor laser, the device structure (A) provides the best optical performance of the three structures of the InP-based surface emitting semiconductor lasers.

Experiments of material of the insulating DBR are also conducted. Similar performances are obtained in surface emitting semiconductor lasers using insulating DBRs made of combinations of material of a low refractive index (SiO₂, Al₂O₃, and CaF₂) and a high refractive index (a-Si, TiO₂, Ta₂O₅, and ZnS).

Surface emitting semiconductor lasers show an excellent optical modulation performance as the length of the optical cavity becomes short, that is, they can perform fast modulation, and they show an excellent electrical modulation performance as the differential resistance becomes low. The device structure (B) can reduce the optical cavity, but requires long growth time to form the semiconductor DBR. This long growth time increases the resistance in the tunnel junction, and therefore deteriorates the electrical modulation performance. The optical output is decreased because of absorption of light by the semiconductor DBR.

Although the device structure (C) can reduce the optical cavity without increasing the resistance of the tunnel junction, the insulating DBR makes the electrical path of current long to increase the transverse current component of the current and therefore increases the differential resistance, thereby deteriorating the electrical modulation performance. If the length of the optical cavity becomes large in order to reduce differential resistance, the optical modulation performance is deteriorated. Further, since the heat radiation performance of the insulating DBR is low, the optical saturation occurs.

In the device structure (A), current flows through the part of the second DBR, i.e., the semiconductor DBR, and thus the transverse component is made low, thereby reducing the device resistance of the device structure (A) and length of the optical cavity. In addition, the growth time to grow the semiconductor DBR is made short as compared with the device structure that does not use the semiconductor DBR as the second DBR. This results in avoiding increase of the resistance of the tunnel junction. Further, since the optical cavity is provided adjacent to the semiconductor DBR, the semiconductor DBR can facilitate the thermal dissipation, thereby increasing the optical output. Furthermore, the combination of the semiconductor DBR and insulating DBR in the second DBR decreases the absorption of light.

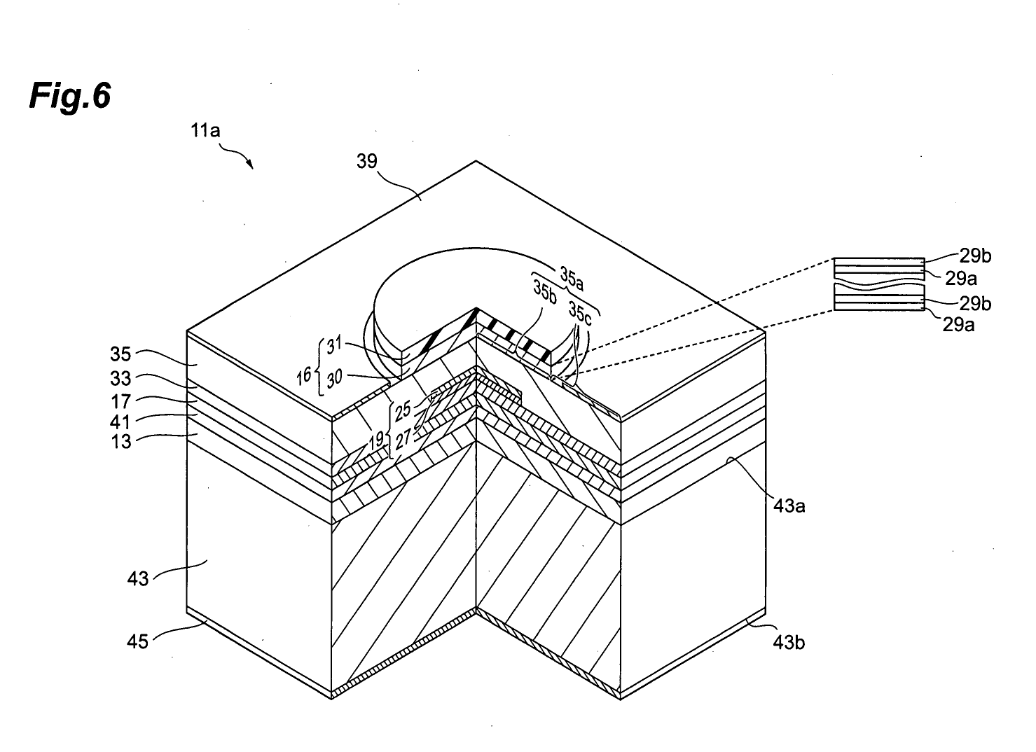

Therefore, the device structure (A) has an excellent optical and electrical modulation performances as well as high output operation. The device structure according to the present embodiment is not limited to the device structure (A). FIG. 6 shows the structure of a modified surface emitting semiconductor laser. In a surface emitting semiconductor laser 11a, a second spacer layer 35 has a primary surface 35a, and the primary surface 35a includes a first area 35b and a second area 35c. The second area 35c surrounds the first area 35b. In the surface emitting semiconductor laser 11a, a second Bragg reflector 16 is located on the first area 35b of the second spacer layer 35, whereas an electrode 39 is located on the second area 35c of the second spacer layer 35.

In the surface emitting semiconductor laser 11a, since the second Bragg reflector 16 is located on the first area 35b of the second spacer layer 35, the first portion 30, i.e. the semiconductor DBR, of the second spacer layer 35 can contribute to heat dissipation.

The first portion 30 includes the third III-V compound semiconductor layers 29a and the fourth III-V compound semiconductor layers 29b. In the surface emitting semiconductor laser 11a, since the first portion 30 of the second DBR 16 is located on the first area 35b of the second spacer layer 35, current does not flow through the first portion 30 of the second DBR 16. Therefore, the third III-V compound semiconductor layers 29a and the fourth III-V compound semiconductor layers 29b are made undoped to avoid unwanted optical absorption thereby.

In the surface emitting semiconductor laser 11a, current from the electrode 39 does not flow through the semiconductor DBR, i.e. the first portion 30. The length of the optical cavity is equal to a value obtained by dividing the laser wavelength by the equivalent refractive index of the optical cavity. This structure is referred to as “device structure (D)” in the following. In this device structure (D), the differential resistance and the maximum optical output at room temperature are 60Ω/3 mW, respectively. The differential resistance and the maximum optical output of the device structure (D) are superior to the device structures (B) and (C). The reason why the differential resistance of the device structure (D) is excellent as compared with the device structure (B) is as follows: the resistance in the tunnel junction of the device structure (D) is made low. The reason why maximum optical output of the device structure (D) is great as compared with the device structure (C) is as follows: the device resistance and heat dissipation of the device structure (D) is made excellent.

Having described and illustrated the principle of the invention in a preferred embodiment thereof, it is appreciated by those having skill in the art that the invention can be modified in arrangement and detail without departing from such principles. Details of devices and steps of the method can be modified as necessary. We therefore claim all modifications and variations coming within the spirit and scope of the following claims.

What is claimed is:

1. A surface emitting semiconductor laser comprising:
a first distributed Bragg reflector including first III-V compound semiconductor layers and second III-V compound semiconductor layers, the first and second III-V compound semiconductor layers being alternately arranged;
a second distributed Bragg reflector including a first portion and a second portion, the first portion including third III-V compound semiconductor layers and fourth III-V compound semiconductor layers, the third and fourth III-V compound semiconductor layers being alternately arranged, the second portion including first insulating layers and second insulating layers, and the first and second insulating layers being alternately arranged;
an active layer provided between the first distributed Bragg reflector and the second distributed Bragg reflector, the active layer being made of III-V compound semiconductor, and the first portion of the second distributed Bragg reflector being provided between the active layer and the second portion;
a junction region including a tunnel junction, the junction region being provided between the active layer and the second distributed Bragg reflector.

2. The surface emitting semiconductor laser according to claim 1, further comprising a first spacer layer, the first spacer layer being provided between the active layer and the second distributed Bragg reflector, the first spacer region including a primary surface, the primary surface having a first area and a second area, the second area surrounding the first area, the junction region having a tunnel mesa, the tunnel mesa being located on the first area, the tunnel mesa being made of a first conductive type III-V compound semiconductor layer and a second conductive type III-V compound semiconductor layer, and the first spacer region being made of a second conductive type III-V compound semiconductor.

3. The surface emitting semiconductor laser according to claim 2, further comprising a second spacer layer, the second spacer layer being provided between the first spacer layer and the second distributed Bragg reflector, the second spacer layer being made of a first conductive type III-V compound semiconductor, the second spacer layer covering a side and a top of the tunnel mesa, and the second spacer layer and the second area of the first spacer layer being arranged to form a junction.

4. The surface emitting semiconductor laser according to claim 1, wherein the third III-V compound semiconductor layers are doped with dopant of a first conductive type and the fourth III-V compound semiconductor layers are doped with dopant of the first conductive type.

5. The surface emitting semiconductor laser according to claim 1, wherein the third and fourth III-V compound semiconductor layers of the second distributed Bragg reflector are undoped.

6. The surface emitting semiconductor laser according to claim 1,
wherein the first portion of the second distributed Bragg reflector has a primary surface, the primary surface includes a first area and a second area, and the second area surrounds the first area, and;
wherein the second portion of the second distributed Bragg reflector is provided on the first area of the second distributed Bragg reflector.

7. The surface emitting semiconductor laser according to claim 6, wherein the third III-V compound semiconductor layers are doped with dopant of a first conductive type and the fourth III-V compound semiconductor layers are doped with dopant of the first conductive type.

8. The surface emitting semiconductor laser according to claim 6, comprising a first electrode, the first electrode being provided on the second area of the first portion of the second distributed Bragg reflector.

9. The surface emitting semiconductor laser according to claim 8, wherein the third III-V compound semiconductor layers are doped with dopant of a first conductive type and the fourth III-V compound semiconductor layers are doped with dopant of the first conductive type.

10. The surface emitting semiconductor laser according to claim 2,
wherein the first portion of the second distributed Bragg reflector has a primary surface, the primary surface includes a first area and a second area, and the second area surrounds the first area, and;
wherein the second portion of the second distributed Bragg reflector is provided on the first area of the second distributed Bragg reflector.

11. The surface emitting semiconductor laser according to claim 10, comprising a first electrode, the first electrode being provided on the second area of the first portion of the second distributed Bragg reflector.

12. The surface emitting semiconductor laser according to claim 9, wherein the third III-V compound semiconductor layers are doped with dopant of a first conductive type and the fourth III-V compound semiconductor layers are doped with dopant of the first conductive type.

13. The surface emitting semiconductor laser according to claim 3,
wherein the first portion of the second distributed Bragg reflector has a primary surface, the primary surface includes a first area and a second area, and the second area surrounds the first area, and;
wherein the second portion of the second distributed Bragg reflector is provided on the first area of the second distributed Bragg reflector.

14. The surface emitting semiconductor laser according to claim 13, comprising a first electrode, the first electrode being provided on the second area of the first portion of the second distributed Bragg reflector.

15. The surface emitting semiconductor laser according to of claim 13, wherein the third III-V compound semiconductor layers are doped with dopant of a first conductive type and the fourth III-V compound semiconductor layers are doped with dopant of the first conductive type.

16. The surface emitting semiconductor laser according to claim 3, wherein the second spacer layer has a primary surface, the primary surface includes a first area and a second area, and the second area surrounds the first area; and
wherein the second distributed Bragg reflector is provided on the first area of the second spacer layer;
the surface emitting semiconductor laser further comprising a first electrode, the first electrode being provided on the second area of the second spacer layer.

17. The surface emitting semiconductor laser according to claim 16, wherein the third and fourth III-V compound semiconductor layers of the second distributed Bragg reflector are undoped.

18. The surface emitting semiconductor laser according to claim 1, wherein the top area of the first portion of the second distributed Bragg reflector is different from that of the second portion of the second distributed Bragg reflector.

19. The surface emitting semiconductor laser according to claim 1, wherein the top area of the second portion of the second distributed Bragg reflector is smaller than the top areas of the first distributed Bragg reflector and the first portion of the second distributed Bragg reflector.

20. The surface emitting semiconductor laser according to claim 1, further comprising a substrate and a second electrode, the first distributed Bragg reflector, second distributed Bragg reflector, active layer and junction region being provided on a first surface of the substrate, and the second electrode being provided on a second surface of the substrate, and the first surface being opposite to the second surface.
